(19) United States
(12) Patent Application Publication
(10) Pub. No.: US 2025/0022974 A1
(43) Pub. Date: Jan. 16, 2025

(54) A SOLAR CELL MODULE AND A SOLAR CELL PANEL

(71) Applicant: Epishine AB, Linköping (SE)

(72) Inventors: Gerrit Boschloo, Uppsala (SE); Thomas Österberg, Linköping (SE)

(21) Appl. No.: 18/711,862

(22) PCT Filed: Nov. 24, 2022
(86) PCT No.: PCT/EP2022/083207

§ 371 Date: May 20, 2024

(30) Foreign Application Priority Data
Nov. 24, 2021 (SE) 2151430-2

(51) Int. Cl. H01L 31/0465; H01L 31/0224; H01L 31/0443; H01L 31/075

(52) U.S. Cl. CPC H01L 31/0465; H01L 31/022425; H01L 31/0443; H01L 31/075

(57) ABSTRACT

The present invention relates to a thin film solar cell module (20) comprising a first solar cell (21a) and a second solar cell (21b) disposed on a substrate (1) and connected in series, wherein the first solar cell (21a) comprises a first bottom electrode layer (22a) disposed on the substrate, a first stack (27) disposed on the first bottom electrode layer (22a), and a first top electrode layer disposed on the first stack (27), wherein the first stack (27) is configured to generate electric current when the first stack (27) is illuminated, the second solar cell (21b) comprises a second bottom electrode layer (22b) disposed on the substrate, a second stack (28) disposed on the second bottom electrode layer (22b), and a second top electrode layer disposed on the second stack (28), wherein the second stack (28) is configured to generate electric current when the second stack (28) is illuminated, wherein the first solar cell (31a; 41a; 51a) further comprises a first by-pass diode (32a; 42a; 52a) electrically connected in parallel with the first stack (27); the first by-pass diode (32a; 42a, 52a) is disposed between the first bottom electrode layer (22a) and the first top electrode layer.

### TECHNICAL FIELD

The present disclosure generally relates to the field of solar cell modules and more specifically to Perovskite solar cell modules.

### BACKGROUND

Conventional series connection of thin film solar cells is illustrated in FIG. 1a, wherein stacks of semiconductor materials are disposed on a substrate and serial connected by connecting the bottom layer of a solar cell with the top layer of an adjacent solar cell to create a solar cell module with a predetermined DC voltage and capacity to generate a current.

In order to prevent malfunction when a solar cell is not generating a current, e.g. due to shading, by-pass diodes may be externally connected in parallel with each solar cell, as illustrated in FIG. 1b.

A drawback with an externally connected by-pass diode is that it requires space to be mounted, which reduces the available active area for solar power production. Another drawback is that the complexity of the solar module increases which increases the cost.

### SUMMARY

An object of the present disclosure is to provide a solar cell module which seeks to mitigate, alleviate, or eliminate one or more of the above-identified deficiencies in the art and disadvantages singly or in any combination and to provide an improved solar cell panel.

The object is obtained by a thin film solar cell module comprising a first solar cell and a second solar cell disposed or arranged on a substrate and connected in series, wherein the first solar cell comprises a first bottom electrode layer disposed on the substrate, a first stack disposed or arranged on the first bottom electrode layer, and a first top electrode layer disposed or arranged on the first stack, wherein the first stack is configured to generate electric current by means of the photovoltaic effect from the first bottom electrode layer to the first top electrode layer when the first stack is illuminated, the second solar cell comprises a second bottom electrode layer disposed or arranged on the substrate, a second stack disposed or arranged on the second bottom electrode layer, and a second top electrode layer disposed or arranged on the second stack, wherein the second stack is configured to generate electric current by means of the photovoltaic effect from the second top electrode layer to the second bottom electrode layer when the second stack is illuminated, and the first top electrode layer and the second top electrode layer are electrically connected. Additionally, the first solar cell further comprises a first by-pass diode electrically connected in parallel with the first stack; and the first by-pass diode is disposed between the first bottom electrode layer and the first top electrode layer.

In relation to this invention a layer that is stated as being disposed on an item, e.g. a layer, may also be referred to as arranged on said item. As stated above each solar cell comprises a bottom electrode and a top electrode. Moreover, a layer that is stated as being disposed on a bottom electrode, or disposed on a first item which in turn is disposed on said bottom electrode, or disposed on a second item which in turn is disposed on said first item, or disposed on a third item which in turn is disposed on said second item, may also be referred to as arranged between the bottom electrode and top electrode of that solar cell. In analogy, said second item may be referred to as being arranged between said first item and said top electrode, and also referred to as being arranged between said first item and said third item (if present).

At manufacturing the by-pass diode may be formed of the same material composition(s) as is used for forming the solar cells. Alternatively, the by-pass diode may be formed of material composition which are different from the ones used for forming the solar cells. Optionally, one or more of the layers forming the current generating stack in a solar cell may be extended so as to form the by-pass diode of that solar cell or so as to form the by-pass diode of an adjacent solar cell.

An advantage with the present invention is that an improved manufacturing method may be used having fewer manufacturing steps, and a more cost efficient manufacturing process. As seen

### BRIEF DESCRIPTION OF THE DRAWINGS

The foregoing will be apparent from the following more particular description of the example embodiments, as illustrated in the accompanying drawings in which like reference characters refer to the same parts throughout the different views. The drawings are not necessarily to scale, emphasis instead being placed upon illustrating the example embodiments.

FIGS. 1a and 1b are illustrations of prior art solar cells and solar cell panel;

FIG. 2 illustrates a first embodiment of a solar cell module;

FIG. 3a illustrates a second embodiment of a solar cell module;

FIG. 3b schematically illustrates a solar cell panel comprising a plurality of solar cell modules of FIG. 3a;

FIG. 4 illustrates a third embodiment of a solar cell module;

FIG. 5 illustrates a fourth embodiment of a solar cell module;

FIGS. 6a-6g illustrates the steps of the manufacturing process for the solar cell module in FIG. 5;

FIG. 7 is a flowchart illustrating embodiments of method steps.

FIG. 8 schematically illustrates a solar cell panel comprising a plurality of solar cell modules of FIG. 3a;

FIGS. 9a and 9b illustrate further embodiments of a solar cell module comprising a photon blocking layer.

FIGS. 10a and 10b are graphs presenting the performance of a solar cell module with the by-pass diode.

FIG. 11 illustrates an example of the solar cell module.

### DETAILED DESCRIPTION

Aspects of the present disclosure will be described more fully hereinafter with reference to the accompanying drawings. The apparatus and method disclosed herein can, however, be realized in many different forms and should not be construed as being limited to the aspects set forth herein. Like numbers in the drawings refer to like elements throughout.

The terminology used herein is for the purpose of describing particular aspects of the disclosure only, and is not intended to limit the invention. As used herein, the singular forms “a”, “an” and “the” are intended to include the plural forms as well, unless the context clearly indicates otherwise. It is understood that the expressions “top” and “bottom” are merely used to facilitate the reading and the true orientation of these layers will depend e.g. on the orientation of the module in use or the orientation of the substrate during manufacturing. If the solar cell module in manufactured by lamination e.g. in a roll to roll process e.g. a roll to sheet process the substrates may be off set from a horizontal orientation; the substrates e.g. have a vertical orientation; so the bottom layer is e.g. to the right of the stack configured to generate an electric current by means of the photovoltaic effect and the top layer is e.g. to the left of said stack.

Material and lamination processes that are generally suitable for manufacturing of solar cell modules are described in WO 2018/150053. As is known in the art, many of the materials and lamination processes described on page 7 to page 27 in WO 2018/150053 may clearly also be used for manufacturing a solar cell module, or solar cell panel, having a by-pass diode arranged between the top and the bottom electrodes as described herein. Some of the example embodiments presented herein are directed towards a thin film solar cell module. As part of the development of the example embodiments presented herein, a problem will first be identified and discussed.

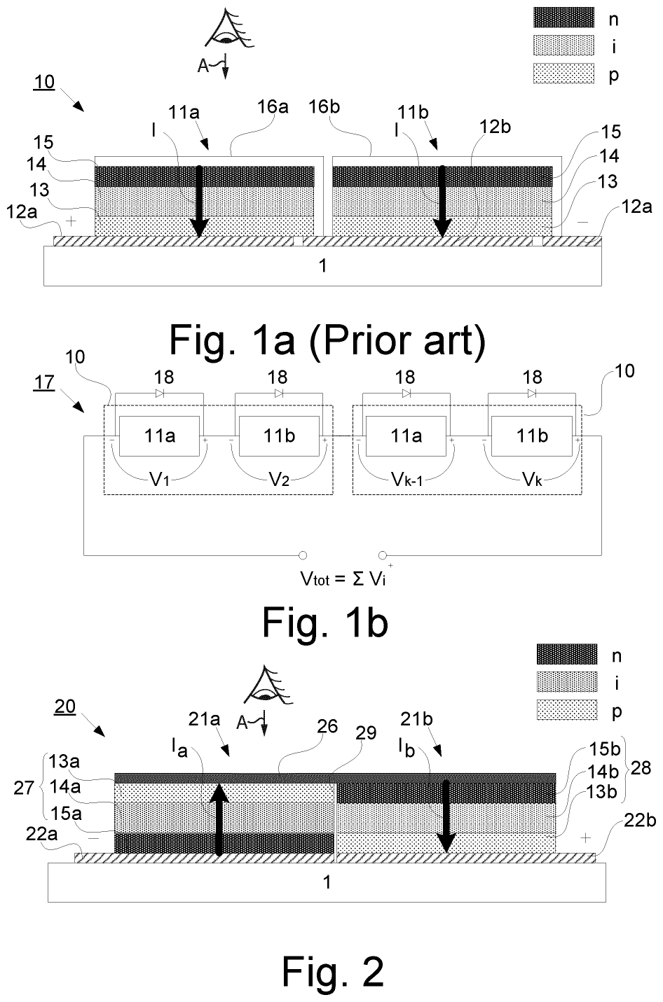

FIG. 1a illustrates a traditional implementation of a solar cell module 10, which requires space for contacting a top electrode layer 16a of a first solar cell 11a with a bottom electrode layer 12b of an adjacent second solar cell 11b to achieve an electrical serial connection of the solar cells. Furthermore, each solar cell comprises a stack of layers arranged between the bottom electrode layer and the top electrode layer, which is configured to generate electric current I by means of the photovoltaic effect from the top electrode layer to the bottom electrode layer when the stack is illuminated, as indicated in FIG. 1a. The stack comprises in this example a p-type semiconductor layer 13 disposed or arranged on the bottom layer 12a or 12b, an absorber layer 14 disposed or arranged on the p-type semiconductor layer 13, and an n-type semiconductor layer 15 disposed or arranged on the absorber layer 14.

In FIG. 1a there is also an eye which views the solar cell module from above, in a direction A orthogonal to the substrate 1. The same eye and direction is also explicitly illustrated in FIGS. 1a, 2, 3a, 4, 9a and 9b; but is applicable to any solar cell module.

FIG. 1b illustrate a solar cell panel 17 comprises a plurality of solar cell modules 10 that are electrically connected in series, and that may comprise external by-pass diodes 18 connected in parallel with each solar cell. Each solar cell has a DC voltage between the bottom and top electrode layers and is configured to generate an electric current when illuminated. The DC voltage over all solar cells is added to a total voltage Vₜₒₜ equal to the sum of the DC voltages of the solar cells: Vₜₒₜ=ΣVᵢ, i=1 to k.

Active surface area of a solar cell panel, i.e. the surface containing stacked material that generate current when illuminated, is crucial to obtain a high efficiency of the solar cell panel.

The present inventors realized that these problems may be minimized or even eliminated by introducing two types of solar cells that are alternatively implemented on a solar cell panel. A first solar cell 21a is configured to generate an electric current Iₐ from a first bottom electrode layer 22a to a first top electrode layer as indicated in FIG. 2, and a second solar cell 21b is configured to generate an electric current I_{b} from a second top electrode layer to a second bottom electrode layer 22b as indicated in FIG. 2. The first and second solar cells are electrically connected in series since the first top electrode layer is in electric contact with the second top electrode layer. The distance between the first solar cell 21a and the second solar cell 21b may be significantly reduced and the active surface of the solar cell panel is increased.

In the present disclosure, the solar cells are exemplified as thin film solar cells, and more specifically to Perovskite solar cells.

It is even possible to improve the efficiency of the solar cells by using different materials in the stacks for the first solar cell 21a compared to the second solar cell 21b. Examples of materials to be used are listed below:

### Substrate

Glass coated with FTO (F-doped SnO₂), ITO (Indium tin oxide, In₂O₃:Sn), AZO (Al-doped ZnO).
Polymer films such as PET or PEN coated with ITO
   n-Type Semiconductor Layer
Metal oxides such as: TiO₂, SnO₂, ZnO.
Electron conducting polymer
Electron conducting molecules, such as: C60, PCBM.
   p-Type Semiconductor Layer
Inorganic p-type semiconductors, such as NiO, CuSCN.
Hole conducting polymers, such as PEDOT, PTAA.
Hole conducting molecules, such as spiro-OMeTAD, copper phthalocyanine (CuPc).

### Absorber Layer

Metal halide perovskites, such as MAPbI₃ (MA=methylammonium)
Organic absorber, such as P3HT/PCBM mixed layer
Inorganic semiconductor, such as CZTS, CIGS, Sb₂S₃

FIG. 2 illustrates a an example of a thin film solar cell module 20 comprising a first solar cell 21a and a second solar cell 21b which are disposed on a substrate 1 and connected in series, wherein the first solar cell 21a comprises a first bottom electrode layer 22a disposed on the substrate 1, a first stack 27 disposed on the first bottom electrode layer 22a, and a first top electrode layer disposed on the first stack 27, wherein the first stack 27 is configured to generate electric current by means of the photovoltaic effect from the first bottom electrode layer 22a to the first top electrode layer when the first stack 27 is illuminated as indicated by the arrow Iₐ.

The first stack 27 comprises an n-type semiconductor layer 15a disposed on the first bottom electrode layer 22a, a first absorber layer 14a disposed on the n-type semiconductor layer 15a, and a p-type semiconductor layer 13a disposed on the first absorber layer 14a, the first top electrode layer is disposed on the p-type semiconductor layer 13a.

The second solar cell 21b comprises a second bottom electrode layer 22b disposed on the substrate 1, a second stack 28 disposed on the second bottom electrode layer 22b, and a second top electrode layer disposed on the second stack 28, wherein the second stack 28 is configured to generate electric current by means of the photovoltaic effect from the second top electrode layer to the second bottom electrode layer 22b when the second stack 28 is illuminated as illustrated by the arrow I_{b}.

The first top electrode layer and the second top electrode layer are electrically connected and in this example the first top electrode layer and the second top electrode layer is a single conductive layer 26.

The thin film solar cell module of FIG. 2 may be manufactured using these steps:

FTO-glass is laser scribed (ca. 50 micron line), to electrically isolate left and right-side parts. On left side SnO₂ (n) is deposited, on right side NiO (p). The outermost left and right parts are left uncovered and used as electrical contact areas. MAPbI3 perovskite is deposited of entire substrate, except for the contact areas. After perovskite deposition, on left side spiro-OMeTAD (p) is deposited, on right side PCBM (n) (contact areas on both sides are left uncovered). Ag is deposited on top of the p and n-layers, electrically connecting the two.

In this conception, the perovskite layer is covering left and right parts and is connected in between. Alternatively, the perovskite layer could be selectively deposited on left and right-side parts, not covering the scribe line 29.

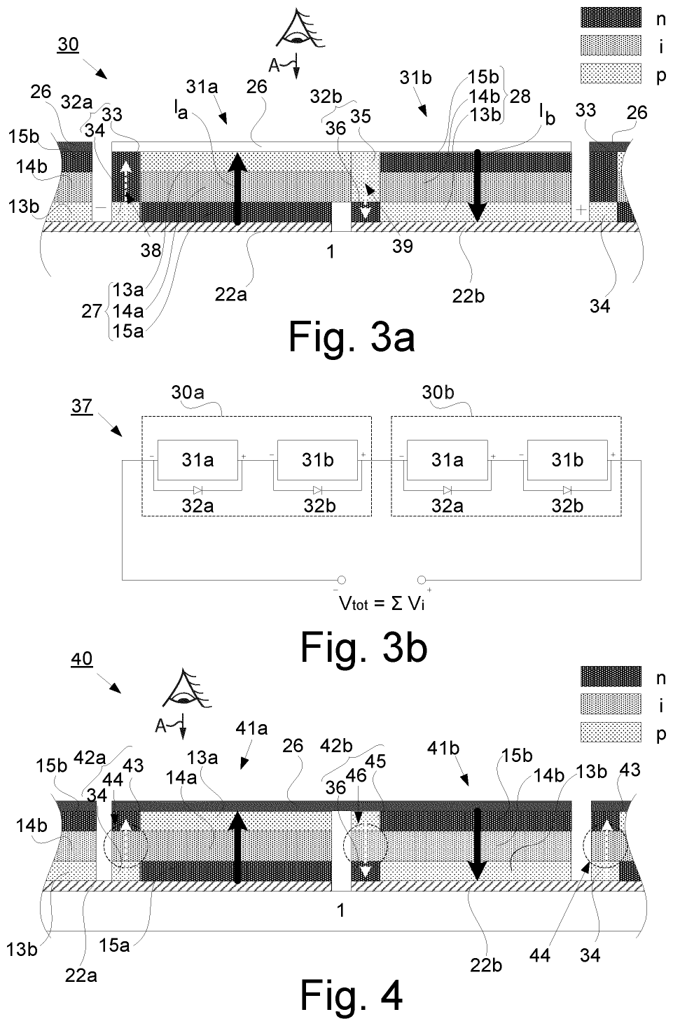

FIG. 3a illustrates a first embodiment of a solar cell module 30, which requires or comprises a solar cell configuration similar to the solar cell module 20 illustrated in FIG. 2. The thin film solar cell module 30 comprising a first solar cell 31a and a second solar cell 31b which are disposed on a substrate 1 and connected in series, wherein the first solar cell 31a comprises a first bottom electrode layer 22a disposed on the substrate 1, a first stack 27 disposed on the first bottom electrode layer 22a, and a first top electrode layer disposed on the first stack 27, wherein the first stack 27 is configured to generate electric current Iₐ by means of the photovoltaic effect from the first bottom electrode layer 22a to the first top electrode layer when the first stack 27 is illuminated as described in FIG. 2.

The first solar cell 31a further comprises a first by-pass diode 32a electrically connected in parallel with the first stack 27. The first by-pass diode 32a is disposed between the first bottom electrode layer 22a and the first top electrode layer and comprises a p-type semiconductor layer 34 disposed on the first bottom electrode layer 22a and an n-type semiconductor layer 33 disposed on the p-type semiconductor layer 34, the n-type semiconductor layer 33 is in electrical contact with the first top electrode layer. The first by-pass diode 32a is configured to conduct a current, as indicated by arrow 38, in case the solar cell is incapable of generating an electric current Iₐ, e.g. due to shading of the first solar cell 31a.

The second solar cell 31b comprises a second bottom electrode layer 22b disposed on the substrate 1, a second stack 28 disposed on the second bottom electrode layer 22b, and a second top electrode layer disposed on the second stack 28, wherein the second stack 28 is configured to generate electric current I_{b} by means of the photovoltaic effect from the second top electrode layer to the second bottom electrode layer 22b when the second stack 28 is illuminated as described in connection with FIG. 2.

The second solar cell 31b further comprises a second by-pass diode 32b electrically connected in parallel with the second stack 28. The second by-pass diode 32b is disposed between the second top electrode layer and the second bottom electrode layer 22b, and comprises an n-type semiconductor layer 36 disposed on the second bottom electrode layer 22b and a p-type semiconductor layer 35 disposed on the n-type semiconductor layer 36, the p-type semiconductor layer 35 is in electrical contact with the first top electrode layer. The second by-pass diode 32b is configured to conduct a current, as indicated by arrow 39, in case the solar cell is incapable of generating an electric current I_{b}, e.g. due to shading of the second solar cell 31b.

The first top electrode layer and the second top electrode layer are electrically connected via a single conductive layer 26.

As seen in FIG. 3a both the first by-pass diode 32a and the second by-pass diode are each spatially arranged between the first bottom electrode layer (22a; 22b) and the first top electrode layer of the respective the solar cells (31a; 31b) when viewed in a direction orthogonal to the substrate 1. The arrow A indicates the direction orthogonal to the substrate 1. Generally, the current passing through the by-pass diode preferably passes in a direction substantially parallel with the direction A. In this embodiment, although the first by-pass diode current 38 passes in a direction opposite to the direction A, the direction of the current is still parallel with direction A. As seen in FIG. 3a the first by-pass diode 32a is arranged directly adjacent to said first stack, and preferably share a common interface therewith. As seen in FIG. 3a two of the layers in the by-pass diode share a common interface with the layers of said first stack. The bottom layer of the first by-pass diode share a common interface with the bottom layer 15a of said first stack, and the top layer of the by-pass diode share a common interface with the top layer 13.a of said first stack.

As seen in FIG. 3a the second by-pass diode 32b is arranged directly adjacent to said first stack, and preferably share a common interface therewith. As seen in FIG. 3a two of the layers in the second by-pass diode share a common interface with the layers of said second stack. The bottom layer of the by-pass diode share a common interface with the bottom layer 13b of said second stack, and the top layer of the by-pass diode share a common interface with the top layer 15b of said second stack. As seen in FIG. 3a the second by-pass diode may optionally share a common interface with two layers of the first stack 27, e.g. the top layer of the by-pass diode may share a common interface with the top layer 13a and the intermediate layer 14a of said first stack.

As seen in FIG. 3a, the top layer of said first stack continuously extends between said first by-pass diode and said second by-pass diode. Optionally and as seen in the figure, the intermediate layer 14a of said first stack continuously extends between said first by-pass diode and said second by-pass diode.

As seen in FIG. 3a, the by-pass diodes may be formed of the same as the materials as those forming the first and/or second stack, although in a suitable order.

FIG. 3b schematically illustrates a solar cell panel 37 comprising a plurality of thin film solar cell modules of FIG. 3a. The total DC voltage over the solar cell panel 37 is the sum of the DC voltage over each respective thin film solar cell, and the current generated by the solar cell panel 37 is the sum of each current generated by the respective thin film solar cell.

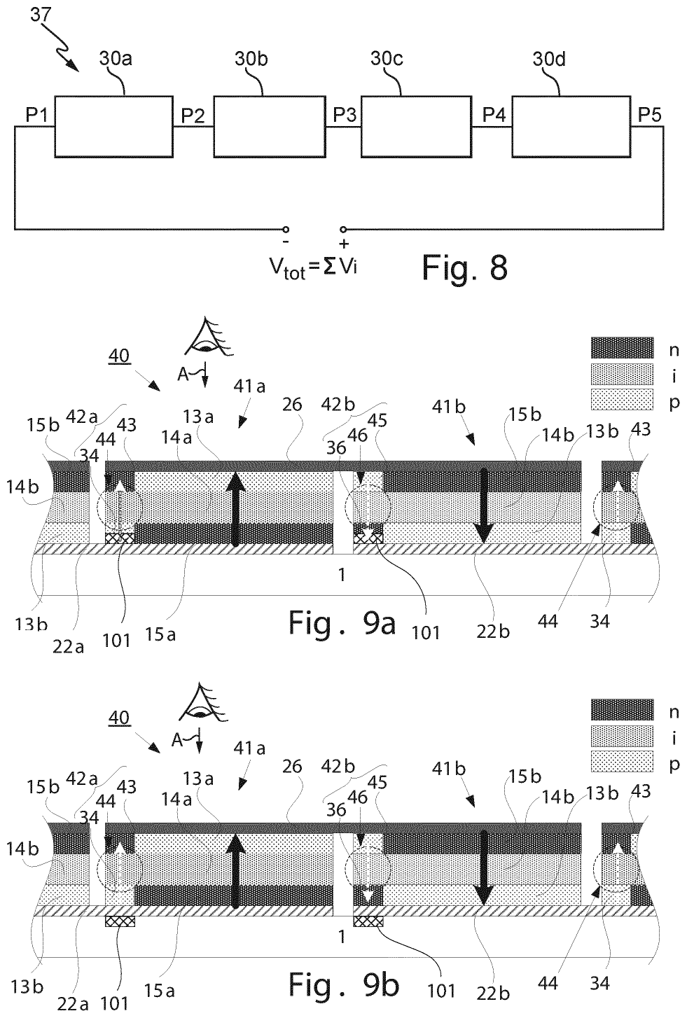

FIG. 8 schematically illustrates a solar cell panel 37 comprising a plurality of thin film solar cell modules of FIG. 3a. The only difference between the solar cell panel shown in FIG. 3b and the solar cell panel shown in FIG. 8, is that in the solar cell panel shown in FIG. 3b there are two solar cell modules (30a, 30b) but in the solar cell panel shown in FIG. 8 there are four solar cell modules (30a, 30b, 30c, 30d). For reasons of simplicity, the schematic circuitry of the respective modules has not been illustrated in FIG. 8, but is the same as illustrated in FIG. 3b. The total DC voltage over the solar cell panel 37 is the sum of the DC voltage over each respective thin film solar cell, and the current generated by the solar cell panel 37 is the sum of each current generated by the respective thin film solar cell. In FIG. 8 the different potentials have been schematically illustrated, where P1<P2<P3<P4<P5, and Vi is roughly equal to Pi+1−Pi.

In relation to this invention it is understood that the terms upstreams and downstreams are to be interpreted such that the intermediate solar cell module 30c between potentials P3 and P4 is arranged electrically downstream of the solar cell module 30d between potentials P4 and P5 and electrically upstream of the solar cell module 30b between potentials P2 and P3, as well as electrically upstream of the solar cell module 30a between potentials P1 and P2. It may be said that it is the potentials between the solar cell modules in use that determine the upstream/downstream direction. It may also be said that it is the direction of the current (as indicated by these potentials) that determine the upstream/downstream direction.

The intermediate solar cell module 30c between potentials P3 and P4 is arranged most adjacent to only the solar cell module 30b between potentials P2 and P3 and solar cell module 30d between potentials P4 and P5.

In FIG. 8 there is schematically illustrated a solar cell panel comprising: a plurality of thin film solar cell modules 30a-d electrically connected in series and each thin film solar cell module is arranged according to any of the preceding claims, wherein said plurality of thin film solar cell modules comprises at least one intermediate solar cell module 30b; 30c, wherein each intermediate solar cell module 30b; 30c is arranged most adjacent to and electrically upstream of a first adjacently arranged solar cell module 30a; 30b and each intermediate solar cell module 30b; 30c is arranged most adjacent to and electrically downstream of a second adjacently arranged solar cell module 30c; 30d. As the modules are connected in series, the first bottom electrode layer 22a of each respective intermediate solar cell module 30b; 30c is electrically connected to a second bottom electrode layer 22b of said first adjacently arranged solar cell module 30a; 30b, and the second bottom electrode layer 22b of each respective intermediate solar cell module 30b; 30c is electrically connected to a first bottom electrode layer 22a of said second adjacently arranged solar cell module 30c; 30d.

FIG. 4 illustrates a second embodiment of a solar cell module 40, which requires or comprises a solar cell configuration similar to the solar cell module 20 in FIG. 2. The thin film solar cell module 40 comprising a first solar cell 41a and a second solar cell 41b which are disposed on a substrate 1 and connected in series, wherein the first solar cell 41a comprises a first bottom electrode layer 22a disposed on the substrate 1, a first stack 27 disposed on the first bottom electrode layer 22a, and a first top electrode layer disposed on the first stack 27, wherein the first stack 27 is configured to generate electric current by means of the photovoltaic effect from the first bottom electrode layer 22a to the first top electrode layer when the first stack 27 is illuminated as described in FIG. 2.

The first solar cell 41a further comprises a first by-pass diode 42a electrically connected in parallel with the first stack 27. The first by-pass diode 42a is disposed between the first bottom electrode layer 22a and the first top electrode layer and comprises a p-type semiconductor layer 34 disposed on the first bottom electrode layer 22a, an intrinsic semiconductor layer 44 disposed on the p-type semiconductor layer 34 and an n-type semiconductor layer 43 disposed on the intrinsic semiconductor layer 44, the n-type semiconductor layer 43 is in electrical contact with the first top electrode layer.

The second solar cell 41b comprises a second bottom electrode layer 22b disposed on the substrate 1, a second stack 28 disposed on the second bottom electrode layer 22b, and a second top electrode layer disposed on the second stack 28, wherein the second stack 28 is configured to generate electric current by means of the photovoltaic effect from the second top electrode layer to the second bottom electrode layer 22b when the second stack 28 is illuminated as described in connection with FIG. 2.

The second solar cell 41b further comprises a second by-pass diode 42b electrically connected in parallel with the second stack 28. The second by-pass diode 42b is disposed between the second top electrode layer and the second bottom electrode layer 22b, and comprises an n-type semiconductor layer 36 disposed on the second bottom electrode layer 22b, an intrinsic semiconductor layer 46 disposed on the n-type semiconductor layer 36 and a p-type semiconductor layer 45 disposed on the intrinsic semiconductor layer 46, the p-type semiconductor layer 45 is in electrical contact with the first top electrode layer.

The first top electrode layer and the second top electrode layer are electrically connected via a single conductive layer 26. Direction of currents are indicated in FIG. 4.

As seen in FIG. 4 both the first by-pass diode 42a and the second by-pass diode are each spatially arranged between the first bottom electrode layer 22a; 22b and the first top electrode layer of the respective the solar cells 41a; 41b when viewed in a direction orthogonal to the substrate 1.

As seen in FIG. 4 the first by-pass diode 32a is arranged directly adjacent to said first stack, and preferably share a common interface therewith. As seen in FIG. 4 two of the layers in the by-pass diode share a common interface with the layers of said first stack. The bottom layer of the first by-pass diode share a common interface with the bottom layer 15a of said first stack, and the top layer of the by-pass diode share a common interface with the top layer 13a of said first stack.

As seen in FIG. 4 the second by-pass diode 32b is arranged directly adjacent to said first stack 42a, and preferably share a common interface therewith. Two of the layers in the second by-pass diode share a common interface with the layers of said second stack. The bottom layer of the second by-pass diode share a common interface with the bottom layer 13b of said second stack, and the top layer of the by-pass diode share a common interface with the top layer 15b of said second stack.

As seen in FIG. 4 both the first and the second by-pass diodes may optionally be confined to their respective solar cells, i.e. the first by-pass diode does not share a common interface with any of the layers in the second stack 28, and the second by-pass diode does not share a common interface with any of the layers in the first stack 27. It is understood that if there is no common interface between two items, there is a separation between these two items.

As seen in FIG. 4, the by-pass diodes may be formed of the same as the materials as those forming the first and/or second stack, although in a suitable order.

FIG. 11 illustrates a third embodiment of a thin film solar cell module 40, where the solar cell module is formed of fewer number of separate layers compared to the other embodiments shown herein.

As seen e.g. by comparing FIG. 11 to FIG. 2, the second by-pass diode 42b may optionally be formed by: extending the bottom layer 15a of said first stack such that it shares a common interface with the bottom layer 13b of said second stack, and by extending the top layer 13a of said first stack such that it shares a common interface with the top layer 15b of said second stack. Also, the first by-pass diode 42a may optionally be formed by: extending the bottom layer 13a of an adjacent stack such that that bottom layer shares a common interface with the bottom layer 13a of said first stack, and by extending the top layer 15b of said adjacent stack such that it shares a common interface with the top layer 13a of said first stack. Moreover, the respective intermediate layer 14a; 14b of said first and second stack 41a; 41b is extended so as to form an intermediate layer of the respective first and second by-pass diode 42a; 42b; while each intermediate layer is confined to its respective stack as seen in FIG. 11. As seen in FIG. 11, two of the layers forming the current generating stack in each solar cell have been extended so as to form the by-pass diode in the adjacent solar cell, and one of the layers forming the current generating stack in each solar cell has been extended so as to form the by-pass diode of that solar cell.

A configuration of the solar cell module where one or more of the layers forming the current generating stack in a solar cell may be extended so as to form the by-pass diode of that solar cell or so as to form the by-pass diode of an adjacent solar cell is advantageous as it reduces the number of processing steps as fewer separate layers are printed.

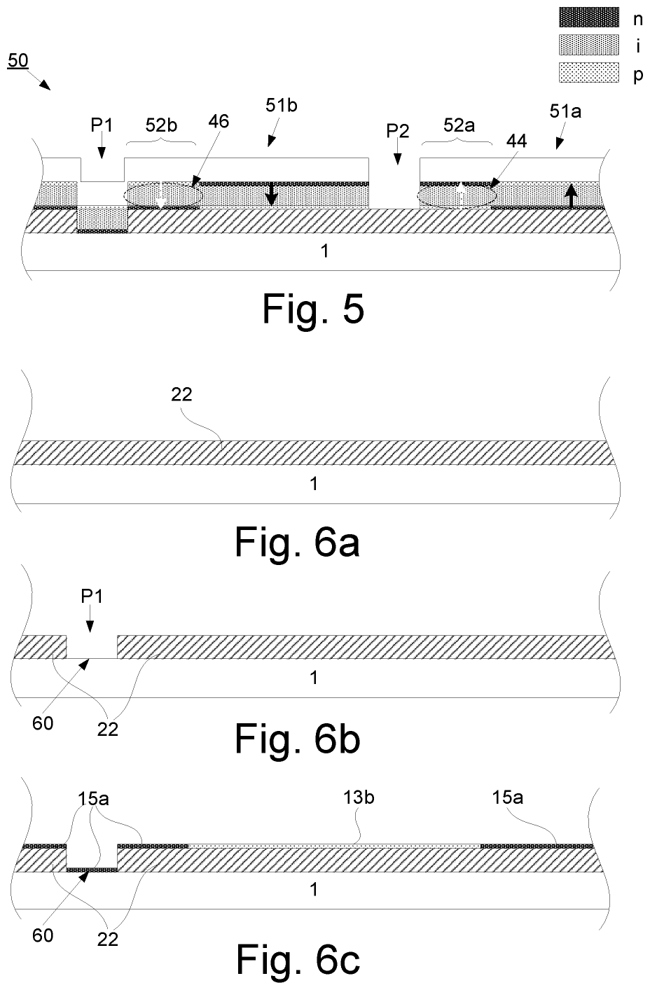

FIG. 5 illustrates a fourth embodiment of a thin film solar cell module 50 which requires or comprises a solar cell configuration similar to the solar cell module 20 illustrated in FIG. 2. The thin film solar cell module 50 comprising a first solar cell 51a and a second solar cell 51b which are disposed on a substrate 1 and connected in series, wherein the first solar cell 51a comprises a first bottom electrode layer disposed on the substrate 1, a first stack disposed on the first bottom electrode layer, and a first top electrode layer disposed on the first stack, wherein the first stack is configured to generate electric current by means of the photovoltaic effect from the first bottom electrode layer to the first top electrode layer when the first stack is illuminated as described in connection with FIG. 2.

The first solar cell 51a further comprises a first by-pass diode 52a electrically connected in parallel with the first stack. The first by-pass diode 52a is disposed between the first bottom electrode layer and the first top electrode layer, as described in connection with FIG. 4.

The second solar cell 51b comprises a second bottom electrode layer disposed on the substrate 1, a second stack disposed on the second bottom electrode layer, and a second top electrode layer disposed on the second stack, wherein the second stack is configured to generate electric current by means of the photovoltaic effect from the second top electrode layer to the second bottom electrode layer when the second stack is illuminated as described in FIG. 2.

The second solar cell 51b further comprises a second by-pass diode 52b electrically connected in parallel with the second stack 5. The second by-pass diode 52b is disposed between the second top electrode layer and the second bottom electrode layer, as described in connection with FIG. 4, and the direction of currents are indicated in FIG. 5.

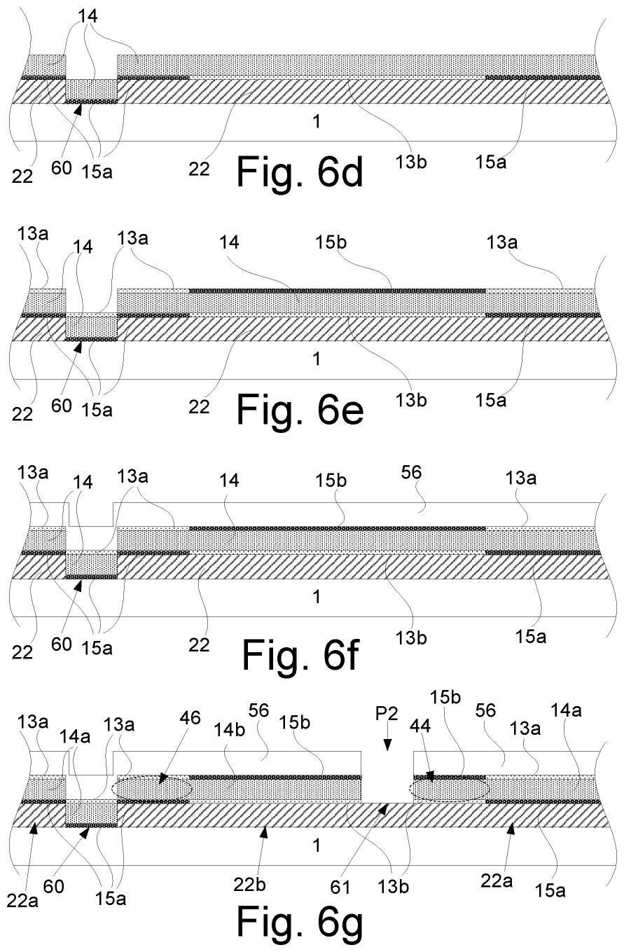

A difference between the thin film solar cell modules of FIGS. 3a, 4 and 5 is the manufacturing process. The thin film solar cell module 50 in FIG. 5 requires a simpler manufacturing process with fewer steps than the manufacturing processes for the thin film solar cells of FIG. 3a or 4. FIGS. 6a-6g illustrates the steps of the manufacturing process for the solar cell module in FIG. 5.

In FIG. 6a a first conductive layer 22, is deposited on a substrate 1. The first conductive layer 22 is divided into several parts, e.g. by laser scribing as indicated by P1, to electrically isolate left and right side part of the thin film solar cell, i.e. isolate the bottom electrode layer of the first solar cell from the bottom electrode layer of the second solar cell. This is illustrated by location 60 in FIG. 6b.

An n-type semiconductor layer 15a and a p-type semiconductor layer 13b are selectively deposited over the complete surface (even at location 60 as illustrated in FIG. 6c), and an absorber layer 14 is thereafter deposited on the n-type semiconductor layer 15a and the p-type semiconductor layer 13b, as illustrated by FIG. 6d. Another n-type semiconductor layer 15b and p-type semiconductor layer 13a are selectively deposited over the absorber layer 14, as illustrated by FIG. 6e. The stacked material in the location 60 of the laser scribed section of the conductive layer will not provide a conductive path between the first solar cell 51a and the second solar cell 51b.

A second conductive layer 56 is provided over the complete surface, as illustrated in FIG. 6f, and the first solar cell 51 a is separated from the second solar cell 51b, e.g. by mechanical scribing as indicated by P2 at location 61, down to the first conductive layer 22.

The bypass diode in the embodiments described herein, might have a drawback in that since both elements, the by-pass diode and the PV stack, are connected in parallel, the current generated from the by-pass diode will recombine with (or counteract) the current of the PV stack, limiting the overall output of the module. A facile solution to mitigate or even remove this effect is to deposit an opaque material 101 that blocks photons from entering into the by-pass diode, or at least significantly reduces the number of photons entering into the by-pass diode. This could e.g. be achieved by using the structures depicted in FIG. 9a or FIG. 9b. In FIG. 9a the photon blocking layer 101 is preferably electrically conducting (any metal); for the embodiment illustrated in FIG. 9a the photon blocking layer is either conducting (e.g. metal) or insulating (e.g. TiO2).

The photon blocking layer is illustrated in a solar cell module arranged as described in relation to FIG. 4 above, but it is understood that it can be used together with any of the by-pass diodes described herein. For configurations where the light is incident on the upper layer, the photon blocking layer may be arranged on that side of the module. For configurations where light is incident on both the upper and lower layer, a photon blocking layer may be arranged on both sides of the module.

The photon blocking layer 101 is preferably arranged between said first substrate 1 and said first by-pass diode 32a; 42a; 52a and configured to prevent at least a portion of the optical radiation incident on said first substrate from reaching said first by-pass diode. Optionally, the average transmission of said photon blocking layer is at most 50% within a wavelength range of 400 nm to 900 nm and more preferably at most 1% within said wavelength.

As illustrated in FIG. 9a, one photon blocking layer 101 may be arranged between said first bottom electrode layer 22a and said first by-pass diode 32a; 42a, 52a; one photon blocking layer 101 may be arranged between said second bottom electrode layer 22b and said second by-pass diode 32b; 42b, 52b.

As illustrated in FIG. 9b, one photon blocking layer 101 may be arranged between said first substrate 1 and said first bottom electrode layer 22a and one photon blocking layer 101 may be arranged between said first substrate 1 and said second bottom electrode layer 22b.

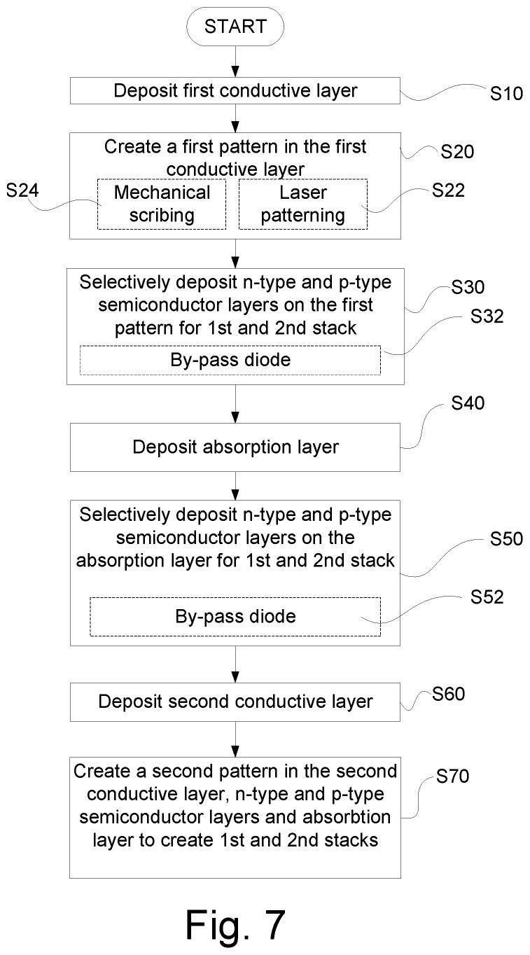

FIG. 7 is a flowchart illustrating embodiments of method steps.

The first conductive layer is deposited on a substrate in step S10, and a pattern is created in the first conductive layer in step S20 to isolate the first solar cell and the second solar cell within each solar cell module. The pattern may for instance be created using laser scribing S22 or Mechanical scribing S24.

The first layer of the first and second stack is thereafter deposited on the substrate with the created first pattern in step S30 by selectively depositing n-type material and p-type material. A first layer for the by-pass diodes may also be deposited as indicated by optional step S32.

An absorber layer is thereafter deposited, step S40, as a second layer in the first and second stack, and a third layer of the first and second stack is thereafter deposited in step S50 on the absorber layer. Optionally another layer is also deposited for the by-pass diode, S52.

A second conductive layer is thereafter deposited on the complete surface, S60, and thereafter a second pattern is created, step S70, in the deposited layers to create the first and second stacks, and optionally the respective by-pass diodes.

An advantage of the proposed module structure is the possibility to include bypass diodes for the solar cells in a cost efficient way. If a cell is shaded, the bypass diode enables the current to by-pass this cell through the adjacent (p-i-n or n-i-p) bypass diode, which in the example below is a solar cell polarized in forward direction. Considering a photocurrent density of 20 mA cm⁻² in the solar module, the current through the bypass diode would be 200 mA cm⁻² if its area is 10% of that of the solar cell. This would correspond to a bypass diode width of 0.5 mm for a solar cell width of 0.50 cm.

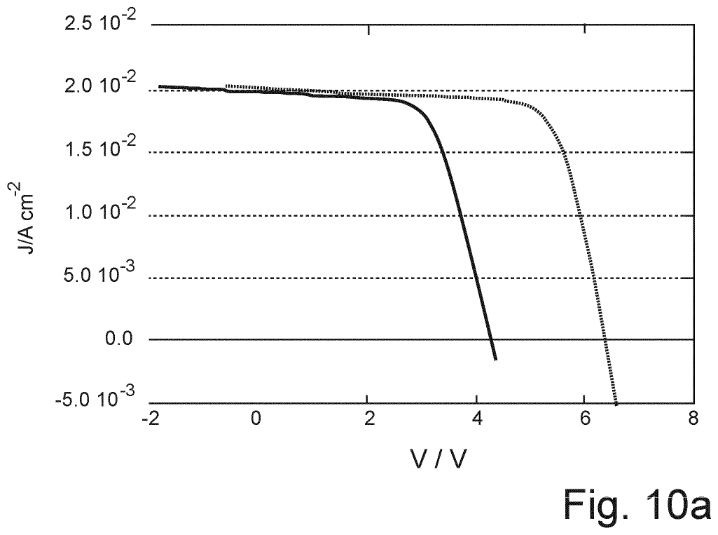

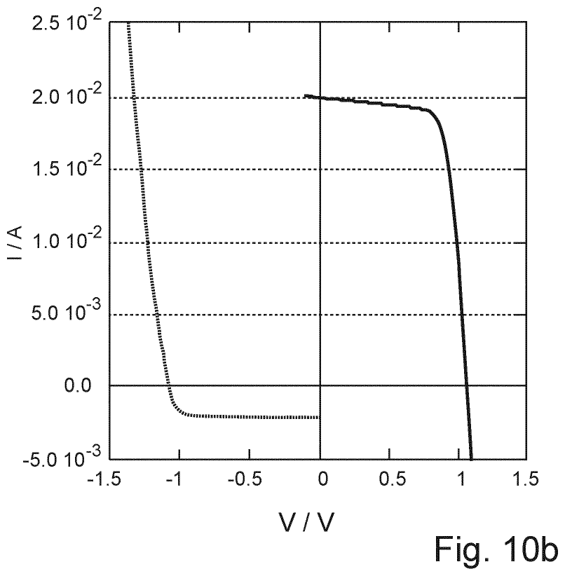

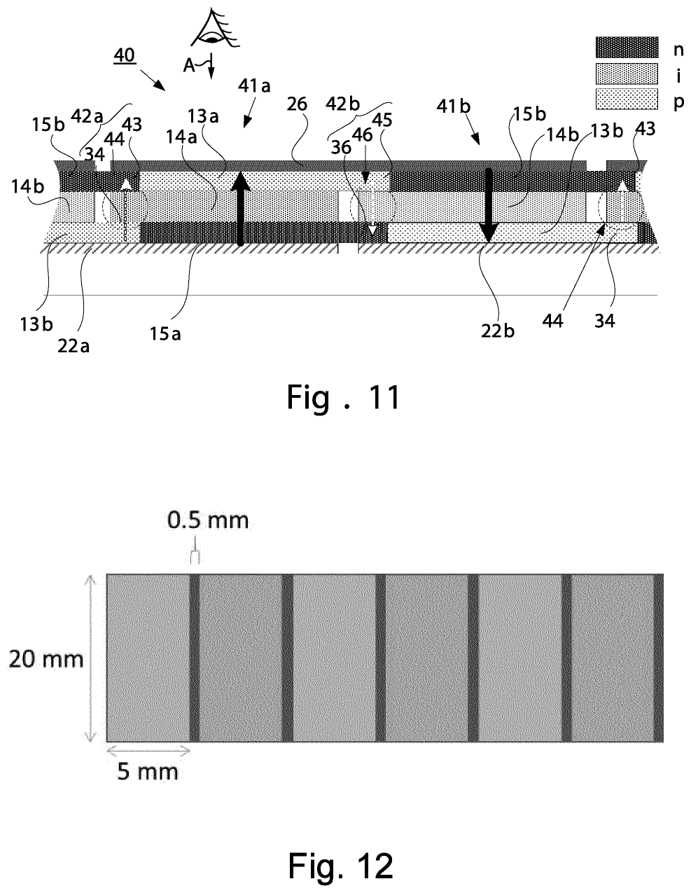

FIG. 10a shows the results of a numerical simulation for a pin-nip module consisting of 6 series-connected cells with integrated bypass diodes and the effect of shading one cell. Simulation details are given below. In more detail FIG. 10a shows JV-curves for a 6-cell pin-nip series connected solar module with integral bypass diodes, under full sun illumination (right most curve) and the same with one cell fully shaded (left most curve).

In order to drive the photocurrent of the 5 active, non-shaded, solar cells through the bypass diode adjacent to the shaded cell, about 1 V (or the output of one cell) is required in this example. The resulting JV-curve is therefore similar to that of 4 cells in series. The power conversion efficiency (PCE) decreases by 40% from 15.7% to 9.15%. Out of this 40% decrease, 17% comes from shading one cell. Without the bypass diode, the PCE would drop to 0%, since no reverse bias breakthrough is included in the model. While the PCE drop is rather high in this example, the important issue is that the shaded cell is protected from a reverse bias of more than about 1 V.

To further increase the performance, it is suggested to leave out or remove the absorber layer in the bypass diodes, for two reasons: The n-i-p and p-i-n diodes will generate unwanted photocurrent in the opposite direction of the solar cell, thus reducing the overall photocurrent of the system. Secondly, the voltage required to drive sufficient current through the bypass diode is relatively high due to the presence of this absorber layer (see below).

The results presented above was calculated using a model which is explained in more detail below:

J-V curves of solar cells are generally reasonably well-described by the Shockley diode equation with additional resistive losses:

$$V = \frac{{nk}_{B} T}{e} ln ( \frac{{J}_{ph} - J}{{J}_{s}} - \frac{V - {JR}_{s}}{{J}_{s} {R}_{p}} + 1 ) - {JR}_{s}$$

where n is the diode quality factor, k_{B} the Boltzmann constant, T absolute temperature, Jₚₕ the generated photocurrent density, Jₛ the reverse bias saturation current density, and Rₛ and Rₚ the series and parallel (or shunt) resistance, respectively. Note that there is no reverse bias breakdown in this model.

The parameters used to simulate a single perovskite cell are:
n 1.5; Jₚₕ(Acm⁻²) 20 E-3; Jₛ(Acm⁻²) 1.80E-14 Rₛ(Ωcm²) 5; Rₚ (Ωcm²) 1000

The resulting solar cell parameters are:
PCE=15.7%; V_{OC}=1.07 V; J_{SC} 20 mA cm⁻²; FF 0.733

For the bypass diode:
n 1.5; Jₚₕ(Acm⁻²) 20 E-3; Jₛ(Acm⁻²) 1.80E-14 Rₛ(Ωcm²) 0.5; Rₚ (Ωcm²) 1000

Same parameters are used, because the diode is essentially the same as the solar cell. The reason for the lower Rₛ is the smaller width of the bypass diode compared to the solar cell, resulting in a less resistive losses in the TCO.

FIG. 10b shows simulated IV curves under 1 sun illumination of the perovskite solar cell (right curve; cell area 1 cm²) and the perovskite bypass diode (left curve; area 0.1 cm²). Note that the bypass diode also creates photocurrent. Relatively high voltage (−1.1 to −1.3 V) on the diode is required to pass current (1 to 20 mA).

In order to calculate the JV curve of the pin-nip solar modules consisting to 6 solar cells with integral bypass diodes in series. The dimensions of the modeled pin-nip solar module with integral bypass diodes: each solar cell was 20 mm high and 5 mm wide, while each by-pass diode was 20 mm high and 0.5 mm wide and in total the pin-nip solar modules was 20 mm high and 33 mm wide (see FIG. 12). The voltage of the JV curve data set was multiplied by 6. Upon shading of one of the cells, the JV curve was approximated as follows: JV curve of 5 cells in series was calculated; next the voltage was decreased by the amount required to drive a certain current value through the bypass diode (see FIG. 10b). The series resistance in the module is mainly due the TCO-coated glass substrate (sheet resistance ˜10 Ohm per square), giving rise to Rₛ of 5 Ωcm² per cell and 0.5 Ωcm² per active bypass diode.

In the described examples the substrate 1 is transparent and illumination of the solar cell modules takes place through the substrate. Alternatively, non-transparent substrates can be used. In that case a transparent conductor, such as ITO, is used as top contact, and illumination takes place from the top side.

Furthermore, semitransparent solar cell modules are possible, with both transparent top contact and transparent substrate. Illumination can take place from either side.

The disclosure relates to a thin film solar cell module comprising, when viewed from above in a direction orthogonal to the substrate, a first solar cell and a second solar cell disposed on a substrate and connected in series, wherein the first solar cell comprises a first bottom electrode layer disposed on the substrate, a first stack disposed on the first bottom electrode layer, and a first top electrode layer disposed on the first stack, wherein the first stack is configured to generate electric current by means of the photovoltaic effect from the first bottom electrode layer to the first top electrode layer when the first stack is illuminated, the second solar cell comprises a second bottom electrode layer disposed on the substrate, a second stack disposed on the second bottom electrode layer, and a second top electrode layer disposed on the second stack, wherein the second stack is configured to generate electric current by means of the photovoltaic effect from the second top electrode layer to the second bottom electrode layer when the second stack is illuminated, and the first top electrode layer and the second top electrode layer are electrically connected.

According to some embodiments, the first top electrode layer and the second top electrode layer is a single conductive layer. Additionally or alternatively, the top electrode layer of said first and/or second solar cell is a metal mesh electrode configured for solar applications. Additionally or alternatively, the bottom electrode layer of said first and/or second solar cell is a metal mesh electrode configured for solar applications. Optionally, the top electrode layer of said first and/or second solar cell is a carbon electrode, or is formed of a composition comprising electrically conductive carbon. Optionally, the bottom electrode layer of said first and/or second solar cell is a carbon electrode, or is formed of a composition comprising electrically conductive carbon.

According to some embodiments, the first stack comprises an n-type semiconductor layer disposed on the first bottom electrode layer, a first absorber layer disposed on the n-type semiconductor layer, and a p-type semiconductor layer disposed on the first absorber layer, the first top electrode layer is disposed on the p-type semiconductor layer.

According to some embodiments, the second stack comprises a p-type semiconductor layer disposed on the second bottom electrode layer, a second absorber layer disposed on the p-type semiconductor layer, and an n-type semiconductor layer disposed on the second absorber layer, the first top electrode layer is disposed on the n-type semiconductor layer.

According to some embodiments, the first solar cell further comprises a first by-pass diode electrically connected in parallel with the first stack, the first by-pass diode is disposed between the first bottom electrode layer and the first top electrode layer.

According to some embodiments, the first by-pass diode further comprises a p-type semiconductor layer disposed on the first bottom electrode layer and an n-type semiconductor layer disposed on the p-type semiconductor layer, the n-type semiconductor layer is in electrical contact with the first top electrode layer.

According to some embodiments, the first by-pass diode further comprises a p-type semiconductor layer disposed on the first bottom electrode layer, an intrinsic semiconductor layer disposed on the p-type semiconductor layer and an n-type semiconductor layer disposed on the intrinsic semiconductor layer, the n-type semiconductor layer is in electrical contact with the first top electrode layer.

According to some embodiments, the second solar cell further comprises a second by-pass diode electrically connected in parallel with the second stack and the second by-pass diode is disposed between the second top electrode layer and the second bottom electrode layer.

According to some embodiments, the second by-pass diode further comprises an n-type semiconductor layer disposed on the second bottom electrode layer and a p-type semiconductor layer disposed on the n-type semiconductor layer, the p-type semiconductor layer is in electrical contact with the first top electrode layer.

According to some embodiments, the second by-pass diode further comprises an n-type semiconductor layer disposed on the second bottom electrode layer, an intrinsic semiconductor layer disposed on the n-type semiconductor layer and a p-type semiconductor layer disposed on the intrinsic semiconductor layer, the p-type semiconductor layer is in electrical contact with the first top electrode layer.

According to some embodiments, the intrinsic semiconductor layer is an absorber layer.

According to some embodiments, the solar cell module comprises Perovskite solar cells.

According to some embodiments, the solar cell module comprises a photon blocking layer arranged between the first substrate and the first by-pass diode, which photon blocking layer is configured to prevent at least a portion of the optical radiation incident on said first substrate from reaching said first by-pass diode. The average transmission of said photon blocking layer is e.g. at most 50% within a wavelength range of 400 nm to 900 nm, and more preferably at most 1% within said wavelength range of 400 nm to 900 nm. According to one example the wavelength range is longer, so the average transmission of said photon blocking layer is e.g. at most 50% within a wavelength range of 400 nm to 1100 nm, and more preferably at most 1% within said wavelength range of 400 to 1100 nm.

According to some embodiments the photon blocking layer is configured to block incident photos at least within a wavelength range of 400 nm to 900 nm.

According to some embodiments, the photon blocking layer is arranged between said first bottom electrode layer and said first by-pass diode. Alternatively, the photon blocking layer may be arranged between the first substrate and the first bottom electrode layer.

According to one embodiment, there is provided a solar cell panel, comprising: a plurality of solar cell modules electrically connected in series, wherein said plurality of thin film solar cell modules comprises at least one intermediate solar cell module, wherein each intermediate solar cell module is arranged most adjacent to and electrically upstream of a first adjacently arranged solar cell module and each intermediate solar cell module is arranged most adjacent to and electrically downstream of a second adjacently arranged solar cell module wherein the first bottom electrode layer of each respective intermediate solar cell module is electrically connected to a second bottom electrode layer of said first adjacently arranged solar cell module, and the second bottom electrode layer of each respective intermediate solar cell module is electrically connected to a first bottom electrode layer of said second adjacently arranged solar cell module.

Each the solar cell module of the solar cell panel may be arranged according to any one of the embodiments described herein.

The disclosure further relates to a solar cell panel comprising a plurality of solar cell modules electrically connected in series, wherein the first bottom electrode layer of a solar cell module is electrically connected to a second bottom electrode layer of a first adjacently arranged solar cell, and the second bottom electrode layer of the solar cell module is electrically connected to a first bottom electrode layer of a second adjacently arranged solar cell.

In the drawings and specification, there have been disclosed exemplary embodiments. However, many variations and modifications can be made to these embodiments. Accordingly, although specific terms are employed, they are used in a generic and descriptive sense only and not for purposes of limitation, the scope of the embodiments being defined by the following claims.

The description of the example embodiments provided herein have been presented for purposes of illustration. The description is not intended to be exhaustive or to limit example embodiments to the precise form disclosed, and modifications and variations are possible in light of the above teachings or may be acquired from practice of various alternatives to the provided embodiments. The examples discussed herein were chosen and described in order to explain the principles and the nature of various example embodiments and its practical application to enable one skilled in the art to utilize the example embodiments in various manners and with various modifications as are suited to the particular use contemplated. The features of the embodiments described herein may be combined in all possible combinations of methods, apparatus, modules, systems, and computer program products.

It should be appreciated that the example embodiments presented herein may be practiced in any combination with each other. It should be noted that the word “comprising” does not necessarily exclude the presence of other elements or steps than those listed and the words “a” or “an” preceding an element do not exclude the presence of a plurality of such elements. It should further be noted that any reference signs do not limit the scope of the claims, that the example embodiments may be implemented at least in part by means of both hardware and software, and that several “means”, “units” or “devices” may be represented by the same item of hardware.

### ITEMIZED LIST OF EMBODIMENTS

Item 1. A thin film solar cell module (20; 30; 40; 50), comprising: a first solar cell (21a; 31a; 41a; 51a) and a second solar cell (21b; 31b; 41b; 51b) disposed on a substrate (1) and connected in series, wherein
the first solar cell (21a; 31a; 41a; 51a) comprises
   a first bottom electrode layer (22a) disposed on the substrate,
   a first stack (27) disposed on the first bottom electrode layer (22a), and
   a first top electrode layer disposed on the first stack (27), wherein the first stack (27) is configured to generate electric current by means of the photovoltaic effect from the first bottom electrode layer (22a) to the first top electrode layer when the first stack (27) is illuminated;
the second solar cell (21b; 31b; 41b; 51b) comprises
   a second bottom electrode layer (22b) disposed on the substrate (1),
   a second stack (28) disposed on the second bottom electrode layer (22b), and
   a second top electrode layer disposed on the second stack (28), wherein the second stack (28) is configured to generate electric current by means of the photovoltaic effect from the second top electrode layer to the second bottom electrode layer (22b) when the second stack (28) is illuminated; and
the first top electrode layer and the second top electrode layer are electrically connected.

Item 2. The thin film solar cell module according to item 1, wherein the first top electrode layer and the second top electrode layer is a single conductive layer (26).

Item 3. The thin film solar cell module according to any of items 1-2, wherein the first stack (27) comprises an n-type semiconductor layer (15a) disposed on the first bottom electrode layer (22a), a first absorber layer (14a) disposed on the n-type semiconductor layer (15a), and a p-type semiconductor layer (13a) disposed on the first absorber layer (14a), the first top electrode layer is disposed on the p-type semiconductor layer (13a).

Item 4. The thin film solar cell module according to any of items 1-3, wherein the second stack (28) comprises a p-type semiconductor layer (13b) disposed on the second bottom electrode layer (22b), a second absorber layer (14b) disposed on the p-type semiconductor layer (13b), and an n-type semiconductor layer (15b) disposed on the second absorber layer (14b), the first top electrode layer is disposed on the n-type semiconductor layer (15b).

Item 5. The thin film solar cell module according to any of items 1-4, wherein the first solar cell (31a; 41a; 51a) further comprises a first by-pass diode (32a; 42a; 52a) electrically connected in parallel with the first stack (27); the first by-pass diode (32a; 42a, 52a) is disposed between the first bottom electrode layer (22a) and the first top electrode layer.

Item 6. The thin film solar cell module according to item 5, wherein the first by-pass diode (32a) further comprises a p-type semiconductor layer (34) disposed on the first bottom electrode layer (22a) and an n-type semiconductor layer (33; 43) disposed on the p-type semiconductor layer (34), the n-type semiconductor layer (33; 43) is in electrical contact with the first top electrode layer.

Item 7. The thin film solar cell module according to item 5, wherein the first by-pass diode (42a; 52a) further comprises a p-type semiconductor layer (34) disposed on the first bottom electrode layer (22a), an intrinsic semiconductor layer (44) disposed on the p-type semiconductor layer (34) and an n-type semiconductor layer (43) disposed on the intrinsic semiconductor layer (44), the n-type semiconductor layer (43) is in electrical contact with the first top electrode layer.

Item 8. The thin film solar cell module according to any of items 1-7, wherein the second solar cell (31b; 41b; 51b) further comprises a second by-pass diode (32b; 42b; 52b) electrically connected in parallel with the second stack (28) and the second by-pass diode (32b; 42b; 52b) is disposed between the second top electrode layer and the second bottom electrode layer (22b).

Item 9. The thin film solar cell module according to item 8, wherein the second by-pass diode (32b) further comprises an n-type semiconductor layer (36) disposed on the second bottom electrode layer (22b) and a p-type semiconductor layer (35; 45) disposed on the n-type semiconductor layer (36), the p-type semiconductor layer (35; 45) is in electrical contact with the first top electrode layer.

Item 10. The thin film solar cell module according to item 8, wherein the second by-pass diode (42b; 52b) further comprises an n-type semiconductor layer (36) disposed on the second bottom electrode layer (22b), an intrinsic semiconductor layer (46) disposed on the n-type semiconductor layer (36) and a p-type semiconductor layer (45) disposed on the intrinsic semiconductor layer (46), the p-type semiconductor layer (45) is in electrical contact with the first top electrode layer.

Item 11. The thin film solar cell module according to any of items 7 or 10, wherein the intrinsic semiconductor layer (44, 46) is an absorber layer.

Item 12. The thin film solar cell module according to any of items 1-11, wherein the solar cell module comprises Perovskite solar cells.

Item 13. A solar cell panel, comprising: a string of thin film solar cell modules according to any of items 1-12 electrically connected in series, wherein the first bottom electrode layer (22a) of a solar cell module is electrically connected to a second bottom electrode layer (22b) of a first adjacently arranged solar cell, and the second bottom electrode layer (22b) of the solar cell module is electrically connected to a first bottom electrode layer of a second adjacently arranged solar cell.

1. A thin film solar cell module, comprising: a first solar cell and a second solar cell disposed on a substrate and connected in series, wherein
the first solar cell comprises
a first bottom electrode layer disposed on the substrate,
a first stack disposed on the first bottom electrode layer, and
a first top electrode layer disposed on the first stack, wherein the first stack is configured to generate electric current by means of the photovoltaic effect from the first bottom electrode layer to the first top electrode layer when the first stack is illuminated;
the second solar cell comprises
a second bottom electrode layer disposed on the substrate,
a second stack disposed on the second bottom electrode layer, and
a second top electrode layer disposed on the second stack, wherein the second stack is configured to generate electric current by means of the photovoltaic effect from the second top electrode layer to the second bottom electrode layer when the second stack is illuminated; and
the first top electrode layer and the second top electrode layer are electrically connected,
wherein the first solar cell further comprises a first by-pass diode electrically connected in parallel with the first stack; and the first by-pass diode is disposed between the first bottom electrode layer and the first top electrode layer.

2. The thin film solar cell module according to claim 1, wherein the first top electrode layer and the second top electrode layer is a single conductive layer.

3. The thin film solar cell module according to claim 1, further comprising a photon blocking layer arranged between said first substrate and said first by-pass diode and configured to prevent at least a portion of the optical radiation incident on said first substrate from reaching said first by-pass diode.

4. The thin film solar cell module according to claim 3, wherein the average transmission of said photon blocking layer is at most 50% within a wavelength range of 400 nm to 900 nm.

5. The thin film solar cell module according to claim 3, wherein said photon blocking layer is arranged between said first bottom electrode layer and said first by-pass diode.

6. The thin film solar cell module according to claim 3, wherein said photon blocking layer is arranged between said first substrate and said first first bottom electrode layer.

7. The thin film solar cell module according to claim 1, wherein the first stack comprises an n-type semiconductor layer disposed on the first bottom electrode layer, a first absorber layer disposed on the n-type semiconductor layer, and a p-type semiconductor layer disposed on the first absorber layer, the first top electrode layer is disposed on the p-type semiconductor layer.

8. The thin film solar cell module according to claim 1, wherein the second stack comprises a p-type semiconductor layer disposed on the second bottom electrode layer, a second absorber layer disposed on the p-type semiconductor layer, and an n-type semiconductor layer disposed on the second absorber layer, the first top electrode layer is disposed on the n-type semiconductor layer.

9. The thin film solar cell module according to claim 1, wherein the first by-pass diode further comprises a p-type semiconductor layer disposed on the first bottom electrode layer and an n-type semiconductor layer disposed on the p-type semiconductor layer, the n-type semiconductor layer is in electrical contact with the first top electrode layer.

10. The thin film solar cell module according to claim 1, wherein the first by-pass diode further comprises a p-type semiconductor layer disposed on the first bottom electrode layer, an intrinsic semiconductor layer disposed on the p-type semiconductor layer and an n-type semiconductor layer disposed on the intrinsic semiconductor layer, the n-type semiconductor layer is in electrical contact with the first top electrode layer.

11. The thin film solar cell module according to claim 1 any one of the preceding claims, wherein the second solar cell further comprises a second by-pass diode electrically connected in parallel with the second stack and the second by-pass diode is disposed between the second top electrode layer and the second bottom electrode layer.

12. The thin film solar cell module according to claim 11, wherein the second by-pass diode further comprises an n-type semiconductor layer disposed on the second bottom electrode layer and a p-type semiconductor layer disposed on the n-type semiconductor layer, the p-type semiconductor layer is in electrical contact with the first top electrode layer.

13. The thin film solar cell module according to claim 11, wherein the second by-pass diode further comprises an n-type semiconductor layer disposed on the second bottom electrode layer, an intrinsic semiconductor layer disposed on the n-type semiconductor layer and a p-type semiconductor layer disposed on the intrinsic semiconductor layer, the p-type semiconductor layer is in electrical contact with the first top electrode layer.

14. The thin film solar cell module according to claim 1, wherein the intrinsic semiconductor layer is an absorber layer.

15. The thin film solar cell module according to claim 1, wherein the solar cell module comprises Perovskite solar cells.

16. A solar cell panel, comprising: a plurality of thin film solar cell modules electrically connected in series and each thin film solar cell module is arranged according to claim 1, wherein said plurality of thin film solar cell modules comprises at least one intermediate solar cell module, wherein each intermediate solar cell module is arranged most adjacent to and electrically upstream of a first adjacently arranged solar cell module and each intermediate solar cell module is arranged most adjacent to and electrically downstream of a second adjacently arranged solar cell module wherein the first bottom electrode layer of each respective intermediate solar cell module is electrically connected to a second bottom electrode layer of said first adjacently arranged solar cell module, and the second bottom electrode layer of each respective intermediate solar cell module is electrically connected to a first bottom electrode layer of said second adjacently arranged solar cell module.

17. A solar cell panel, comprising: a string of thin film solar cell modules according to claim 1 electrically connected in series, wherein the first bottom electrode layer of a solar cell module is electrically connected to a second bottom electrode layer of a first adjacently arranged solar cell, and the second bottom electrode layer of the solar cell module is electrically connected to a first bottom electrode layer of a second adjacently arranged solar cell.

18. The thin film solar cell module according to claim 4, wherein the average transmission of said photon blocking layer is at most 1% within said wavelength range of 400 nm to 900 nm.
